(19) United States
(12) Patent Application Publication
(10) Pub. No.: US 2025/0362542 A1
(43) Pub. Date: Nov. 27, 2025

(54) WIDE COVERAGE LIGHT EMITTING AND DRIVING DEVICE PACKAGE, BACKLIGHT UNIT, AND DISPLAY APPARATUS

(71) Applicant: Global Technologies Co., LTD, Hwaseong-si Gyeonggi-do (KR)

(72) Inventors: Min Seon KIM, Hwaseong-si Gyeonggi-do (KR); Seung Hyun OH, Gwangju-si Gyeonggi-do (KR); Jung Hyun PARK, Osan-si Gyeonggi-do (KR)

(73) Assignee: Global Technologies Co., LTD, Hwaseong-si Gyeonggi-do (KR)

(21) Appl. No.: 19/217,858

(22) Filed: May 23, 2025

(30) Foreign Application Priority Data
May 27, 2024 (KR) 10-2024-0068706

(51) Int. Cl. G02F 1/13357

(52) U.S. Cl. CPC G02F 1/133603; G02F 1/133621

(57) ABSTRACT

A wide-area light-emitting driving package, a backlight unit, and a display device are disclosed. The wide-area light-emitting driving package may include a substrate, a terminal layer formed on one surface of the substrate, a wiring layer formed on the opposite surface of the substrate and electrically connected to the terminal layer through through-electrodes, at least one light-emitting device mounted on a portion of the wiring layer and disposed at a peripheral region of the substrate, a driving element mounted on another portion of the wiring layer, disposed at a central region of the substrate, and configured to drive the light-emitting device, and a protective member covering and protecting the light-emitting device and the driving element.

### CROSS-REFERENCE TO RELATED PATENT APPLICATION

The present application claims priority under 35 U.S.C. § 119(a) to Korean Patent Application No. 10-2024-0068706, filed in the Korean Intellectual Property Office on May 27, 2024, the entire contents of which application is incorporated herein by reference.

### BACKGROUND

### 1. Field of the Disclosure

The present disclosure relates to a wide coverage light emitting and driving device package, a backlight unit, and a display apparatus. More particularly, it relates to a wide coverage light emitting and driving device package having a broad light irradiation area, and to a backlight unit and a display apparatus employing the same.

### 2. Description of the Related Art

Conventionally, a light emitting device package is configured by mounting a single light emitting diode (LED) on a substrate and molding it with a molding material. When such a single-focal point light emitting device package is used in a backlight unit, the light irradiation area is narrow. To address this, an additional optical lens capable of refracting or diffusing the light along the optical path has been attached.

However, the addition of such an optical lens increases the number of components and manufacturing processes, resulting in higher product costs and decreased productivity. Furthermore, optical losses due to diffusion and refraction at the interface of the optical lens cause a significant decrease in optical efficiency. In the case of a backlight unit, the focal length becomes longer, thereby increasing the required optical distance. This results in a thicker backlight unit or a greater number of light emitting device packages needed to cover the same area, making it difficult to achieve optical uniformity (display uniformity).

Furthermore, in a conventional backlight unit using LED packages, not only the LED packages but also separate driving components, such as driver ICs for operating the LED packages, are mounted on the printed circuit board (PCB). As a result, the wiring layer of the PCB becomes extremely complex, necessitating a multilayer wiring structure, thereby increasing the complexity of the circuit and the manufacturing cost of the PCB. In addition, the number of components such as driving components increases, leading to a significant rise in product cost as well as manufacturing process costs, including bonding processes. Moreover, various problems occur, such as deviation in the emission angle caused by positional misalignment during assembly of the optical lens.

Moreover, since the light emitting devices and the driving components are mounted on the same planar PCB, the overall package and circuit structure tends to become larger, leading to increased raw material costs.

### SUMMARY OF THE DISCLOSURE

In order to achieve the above objectives, a wide-area light-emitting driving package according to an embodiment of the present disclosure includes a substrate having a terminal layer formed on one surface thereof and a wiring layer formed on an opposite surface thereof, the wiring layer being electrically connected to the terminal layer through through-electrodes. At least one light-emitting device is mounted on a portion of the wiring layer and are disposed at an outer peripheral region of the substrate. A driving element for driving the light-emitting device is mounted on another portion of the wiring layer and is disposed at a central region of the substrate. In addition, a protective member covers and protects the light-emitting device and the driving element.

### BRIEF DESCRIPTION OF THE DRAWINGS

The above and other features and advantages of the present disclosure will become more apparent by describing in detail embodiments thereof with reference to the attached drawings in which:

FIG. 1 is a perspective view illustrating a wide-area light-emitting driving package according to some embodiments of the present disclosure.

FIG. 2 is a bottom view illustrating the wide-area light-emitting driving package shown in FIG. 1.

FIG. 3 is a plan view illustrating the wide-area light-emitting driving package shown in FIG. 1.

FIG. 4 is a cross-sectional view illustrating the wide-area light-emitting driving package shown in FIG. 1.

FIG. 5 is a perspective view illustrating the external appearance of a wide-area light-emitting driving package according to some other embodiments of the present disclosure.

FIG. 6 is a perspective view illustrating the external appearance of a wide-area light-emitting driving package according to still another embodiment of the present disclosure.

FIG. 7 is a perspective view illustrating the external appearance of a wide-area light-emitting driving package according to yet another embodiment of the present disclosure.

FIG. 8 is a plan view illustrating the light irradiation area of a wide-area light-emitting driving package according to some embodiments of the present disclosure.

FIG. 9 is a plan view illustrating a backlight unit according to some embodiments of the present disclosure.

FIG. 10 is a plan view illustrating a display device according to some embodiments of the present disclosure.

FIGS. 11 to 13 are cross-sectional views sequentially illustrating a manufacturing process of a wide-area light-emitting driving package according to some embodiments of the present disclosure.

FIG. 14 is a flowchart illustrating a manufacturing method of a wide-area light-emitting driving package according to some embodiments of the present disclosure.

### DETAILED DESCRIPTION OF THE EMBODIMENTS

Hereinafter, preferred embodiments of the present disclosure will be described in detail with reference to the accompanying drawings.

The embodiments of the present disclosure are provided to more fully explain the disclosure to those skilled in the art. The following embodiments may be modified into various other forms, and the scope of the present disclosure is not limited to the following embodiments. Rather, these embodiments are provided to thoroughly and completely convey the concept of the disclosure to those skilled in the art. In addition, the thicknesses or sizes of the various layers shown in the drawings are exaggerated for the sake of clarity and convenience of explanation.

Throughout the specification, when an element such as a film, region, or substrate is referred to as being “on,” “connected to,” “stacked on,” or “coupled to” another element, it may mean that the element is directly on, connected to, stacked on, or coupled to the other element, or that there may be another element intervening therebetween.

In contrast, when an element is referred to as being “directly on,” “directly connected to,” or “directly coupled to” another element, it should be understood that there are no intervening elements between them. The same reference numerals denote the same elements throughout the drawings. As used herein, the term “and/or” includes any and all combinations of one or more of the listed items.

It is also noted that, although terms such as “first” and “second” may be used to describe various components, regions, layers, or parts, such terms are merely used to distinguish one component, region, layer, or part from another, and do not limit the components, regions, layers, or parts. Thus, a first component, region, layer, or part may be referred to as a second component, region, layer, or part without departing from the teachings of the present disclosure.

The present disclosure relates to a wide-area light-emitting driving package, a backlight unit, and a display device. More particularly, the present disclosure aims to solve various problems, including those described above, by providing a multifocal package in which a plurality of micro-LEDs are arranged around a driving element. Through this configuration, it is possible to achieve high luminous flux and a wide emission angle, reduce the number of components to lower the product cost, and significantly enhance productivity. However, these objectives are merely exemplary and are not intended to limit the scope of the disclosure.

According to an embodiment of the present disclosure configured as described above, it is possible to achieve high luminous flux and a wide emission angle by constructing a multifocal package in which a plurality of micro-LEDs are arranged around a driving element.

In addition, it is possible to reduce the number of components, thereby lowering the product cost and manufacturing cost, significantly enhance productivity, minimize the circuit complexity of the printed circuit board when applied to a backlight unit, and expand the light irradiation area to greatly improve light efficiency and reduce the required number of components.

Moreover, the thickness of the product can be reduced, and since the molding member also functions as a lens, various components are integrated, thereby preventing variations in component alignment and deviations in the emission angle.

Of course, these effects are merely exemplary and are not intended to limit the scope of the present disclosure.

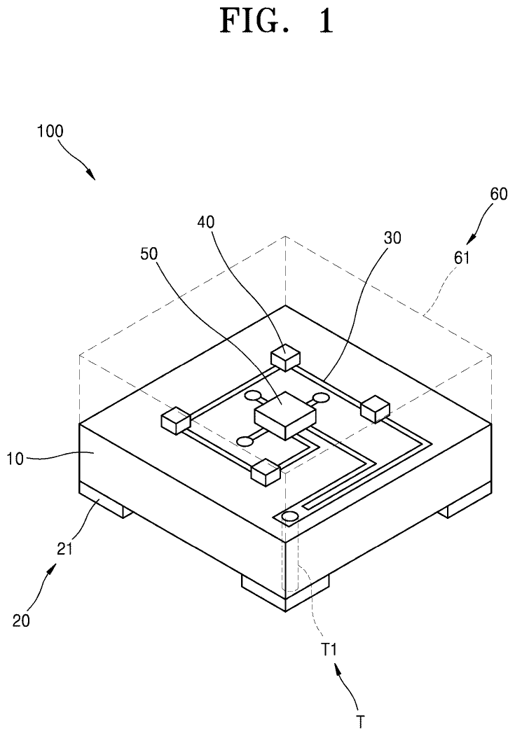

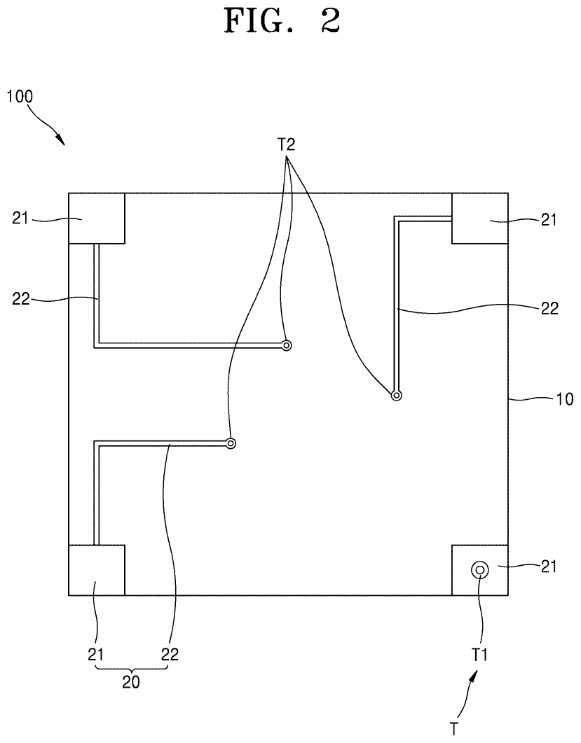

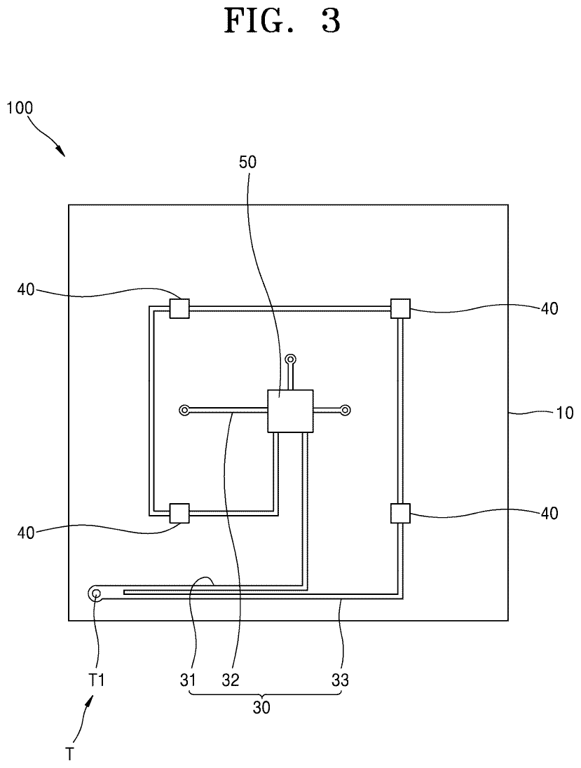

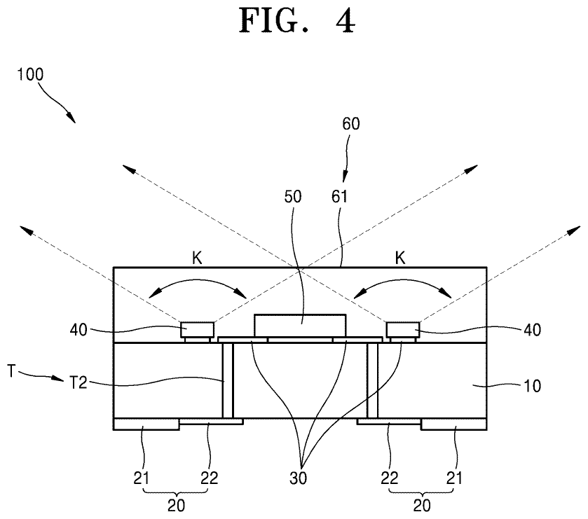

FIG. 1 is a perspective view illustrating a wide-area light-emitting driving package 100 according to some embodiments of the present disclosure, FIG. 2 is a bottom view of the wide-area light-emitting driving package 100 shown in FIG. 1, FIG. 3 is a plan view of the wide-area light-emitting driving package 100 shown in FIG. 1, and FIG. 4 is a cross-sectional view of the wide-area light-emitting driving package 100 shown in FIG. 1.

First, as illustrated in FIGS. 1 to 4, a wide-area light-emitting driving package 100 according to some embodiments of the present disclosure may largely include a substrate 10, a terminal layer 20, a wiring layer 30, at least one light-emitting device 40, a driving element 50, and a protective member 60. The at least one light-emitting device 40 may include a plurality of light-emitting devices.

The substrate 10 may be, for example, at least partially formed of an insulating material, and may include a printed circuit board (PCB) that is single-layered or multi-layered, a ceramic substrate, a metal substrate, or a board structure. The substrate 10 may have sufficient strength and durability to support the light-emitting devices 40, the driving element 50, and the protective member 60, and may have a plate-like structure.

It should be understood, however, that the substrate 10 is not limited to the illustrated examples and may be formed in a wide variety of three-dimensional shapes depending on the specifications, types, or shapes of the packages.

The terminal layer 20 may be, for example, a conductive layer formed on one surface, that is, a bottom surface of the substrate 10.

More specifically, as illustrated in FIG. 2, the terminal layer 20 may include a at least one pad portion 21 formed at an outer corner region of the bottom surface of the substrate 10 and an extension portion 22 extending from the at least one pad portion 21 toward a central region of the bottom surface in a fade-in manner.

The at least one pad portion 21 may include, for instance, a power terminal (Vdd), a ground terminal (Vss), a digital input terminal (Din), and a digital output terminal (Dout).

However, the shape and type of the terminal layer 20 are not limited to the illustrated examples, and various other forms and types of terminal layers may also be applied.

The wiring layer 30 may be, for example, a conductive layer formed on the opposite surface, that is, the top surface of the substrate 10, and may be electrically connected to the terminal layer 20 through through-electrodes (T).

More specifically, as illustrated in FIG. 3, the wiring layer 30 may include a first wiring portion 31 having one part electrically connected to a pad through-electrode T1 formed at the ground terminal (Vss) within the at least one pad portion 21 and another part connected to the driving element 50, a second wiring portion 32 having one part electrically connected to extension through-electrodes T2 formed respectively at the power terminal (Vdd), the digital input terminal (Din), and the digital output terminal (Dout) within the extension portion 22 and another part connected to the driving element 50, and a third wiring portion 33 having one part connected to the driving element 50, another part connected to a plurality of the light-emitting devices 40, and a further part electrically connected to the pad through-electrode T1.

The third wiring portion 33 may be formed in a spiral shape that progressively expands outwardly from the driving element 50, through the plurality of light-emitting devices 40, to the pad through-electrode T1, in an angular or rounded manner, thereby enhancing the integration density of the package.

However, the shape and type of the wiring layer 30 are not limited to the illustrated examples, and various other forms and types of wiring layers may also be applied.

Additionally, although not illustrated, the wide-area light-emitting driving package 100 according to some embodiments of the present disclosure may further include an underfill member filled between the substrate 10 and the light-emitting devices 40 or between the substrate 10 and the driving element 50, and a conductive adhesive member applied onto the wiring layer 30.

The light-emitting devices 40 may be mounted on a portion of the wiring layer 30 and disposed at an outer peripheral region of the substrate 10, and may serve as a light-output device.

More specifically, the light-emitting devices 40 may include at least one selected from a red LED, a green LED, a blue LED, a white LED, and combinations thereof to form a backlight illumination source, or may be a micro-LED or mini-LED capable of forming a display pixel by combining red, green, and blue LED.

The light-emitting devices 40 may be, for example, a flip-chip type LED (Light Emitting Diode) in which a first pad and a second pad are formed on a bottom surface. However, the light-emitting devices 40 is not limited to the flip-chip type and may also be an LED including various colored inorganic light-emitting chips with pads formed on an upper surface in a non-flip type structure. Such a light-emitting devices 40 may include not only a general LED but also any type of LED such as a mini-LED or a micro-LED.

In addition, although not illustrated, various types of light-emitting devices may also be applied, including those in which bonding wires are connected to terminals, those in which bonding wires are partially connected to only a first terminal or a second terminal, and horizontal or vertical type light-emitting devices. Nevertheless, in order to achieve miniaturization and thinning of the product, a flip-chip type structure may be preferable.

The driving element 50 may be mounted on another portion of the wiring layer 30 and disposed at a central region of the substrate 10, and may be a driver IC having at least one channel for driving the light-emitting devices 40.

More specifically, the driving element 50 may include at least one display driver integrated circuit (DDIC).

That is, the driving element 50 may be a driving component such as a driver IC electrically connected to the light-emitting devices 40 and configured to drive the light-emitting devices 40.

The driving element 50 may include a driving circuit therein, wherein the driving circuit may be configured to supply power to the light-emitting devices 40, control a driving voltage, process feedback signals, control the driving brightness of the light-emitting devices 40, or adjust the luminous flux of the light-emitting devices 40 according to a reference luminous flux of other light-emitting devices. The driving element 50 is not limited to the illustrated examples and may be formed in a variety of three-dimensional shapes depending on the specifications, types, or configurations of the packages.

As illustrated in FIGS. 1 to 4, the light-emitting devices 40 may be symmetrically arranged around the driving element 50 in diagonal or cross directions, using overlapping light emission angles (K) to achieve wide coverage of the optical path.

More specifically, as illustrated in FIG. 3, the light-emitting devices 40 may include two or more LEDs (four in the illustrated embodiment) arranged respectively in a front-left direction, a front-right direction, a rear-left direction, and a rear-right direction with respect to the driving element 50. However, the arrangement of the light-emitting devices 40 is not limited to the illustrated configuration, and although not shown, the light-emitting devices 40 may alternatively be arranged in forward, backward, leftward, and rightward directions around the driving element 50.

The protective member 60 may be, for example, a transmissive member covering and protecting the light-emitting devices 40 and the driving element 50.

More specifically, the protective member 60 may be formed by molding on the wiring layer 30 and may include at least one transmissive material or light-conversion material selected from silicone, epoxy, phosphor layers, quantum dots, light-transmissive materials, or combinations thereof.

Accordingly, when power signals, power supply signals, and digital input signals are input through the terminal layer 20 formed on the bottom surface of the substrate 10, the electrical signals are transmitted to the wiring layer 30 formed on the top surface of the substrate 10 through the through-electrodes (T). The input signals may first be provided to the driving element 50.

Then, drive signals generated by the driving element 50 in response to the input signals are supplied to the four light-emitting devices 40 through the wiring layer 30, resulting in wide-area emission by a multi-focal light source having multiple light emission angles (K).

Further, a digital output signal may be output through the wiring layer 30, the through-electrodes (T), and the terminal layer 20.

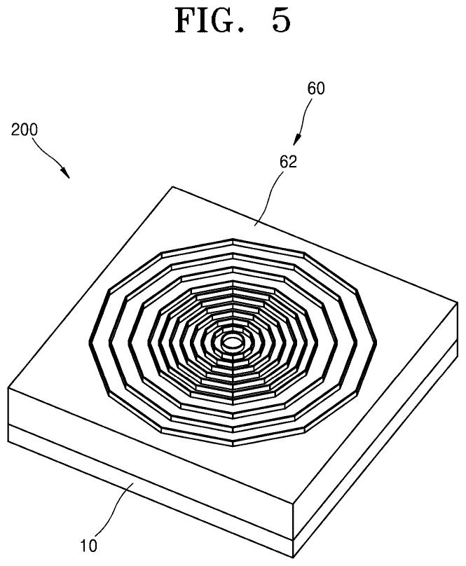

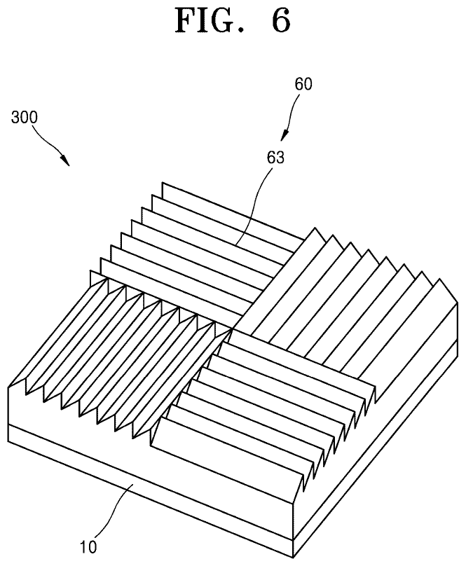

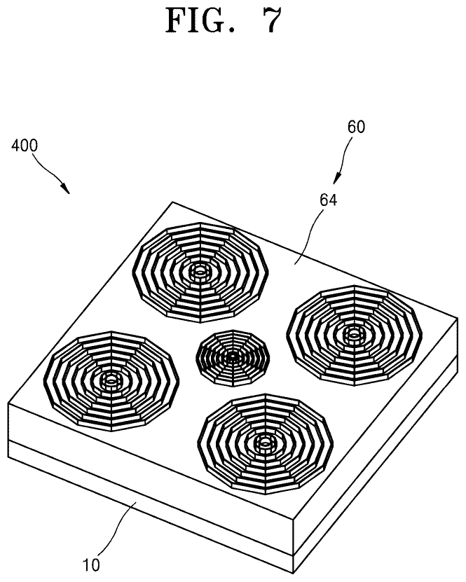

FIG. 5 is a perspective view illustrating a wide-area light-emitting driving package 200 according to some other embodiments of the present disclosure, FIG. 6 is a perspective view illustrating a wide-area light-emitting driving package 300 according to yet another embodiment of the present disclosure, and FIG. 7 is a perspective view illustrating a wide-area light-emitting driving package 400 according to yet another embodiment of the present disclosure.

As illustrated in FIGS. 1 and 4, the protective member 60 may be, for example, a planar molding member 61 having at least a flat light-emitting surface.

However, the protective member 60 is not limited to the illustrated example and may be, for example, a single concentric molding member 62, as illustrated in FIG. 5, which is formed in a circular or polygonal shape with multiple concentric circles centered around a single point, or a prism-shaped molding member 63, as illustrated in FIG. 6, which is configured to disperse light in multiple directions by partitioning into regions corresponding to the light-emitting devices 40, or a multiple concentric molding member 64, as illustrated in FIG. 7, which is formed in circular or polygonal shapes with multiple concentric circles centered around respective multiple points corresponding to the light-emitting devices 40.

Accordingly, according to the present disclosure, a multi-focal package can be constructed by arranging two or more light-emitting devices 40, that is, a plurality of micro-LEDs, around the driving element 50, thereby achieving high luminous flux and a wide emission angle. Additionally, by integrating the lens function into the molding member and reducing the number of components, it is possible to lower the product cost and manufacturing cost and significantly improve productivity.

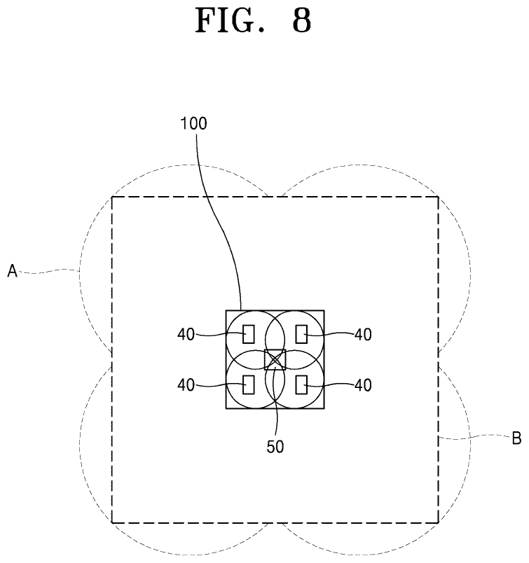

FIG. 8 is a plan view illustrating a light irradiation area A of a wide-area light-emitting driving package 100 according to some embodiments of the present disclosure.

As illustrated in FIG. 8, the light irradiation area A of the wide-area light-emitting driving package 100 according to some embodiments of the present disclosure can sufficiently cover a backlight area B. Therefore, even while reducing the thickness of a single backlight unit, it is possible to achieve a sufficient backlight effect using only the wide-area light-emitting driving package 100. Moreover, the backlight unit can minimize the circuit complexity of the printed circuit board, expand the light irradiation area to improve light efficiency, significantly reduce the number of required components, and prevent variations in component alignment and deviations in emission angle by integrating components such as the molding member functioning as a lens.

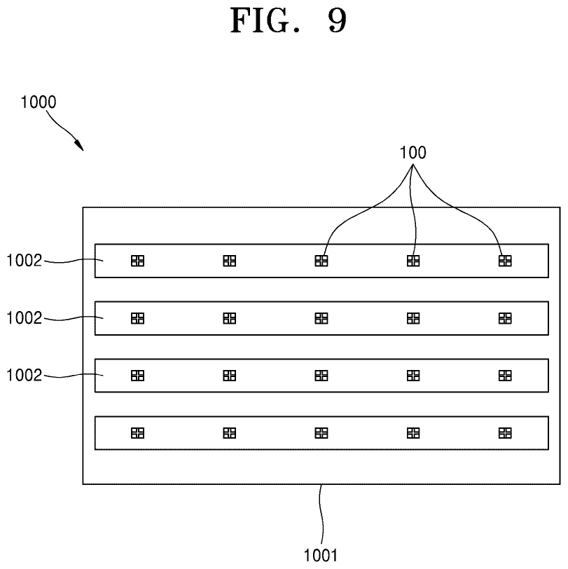

FIG. 9 is a plan view illustrating a backlight unit 1000 according to some embodiments of the present disclosure.

As illustrated in FIG. 9, the backlight unit 1000 according to some embodiments of the present disclosure may include the wide-area light-emitting driving packages 100 to 400 mounted on a bar-type or fork-type printed circuit board 1002 formed inside a rectangular frame 1001.

Therefore, the backlight unit 1000 according to the present disclosure can minimize the circuit complexity of the printed circuit board 1002, expand the light irradiation area to improve light efficiency, significantly reduce the number of required components, and prevent variations in component alignment and deviations in emission angle by integrating components such as the molding member functioning as a lens.

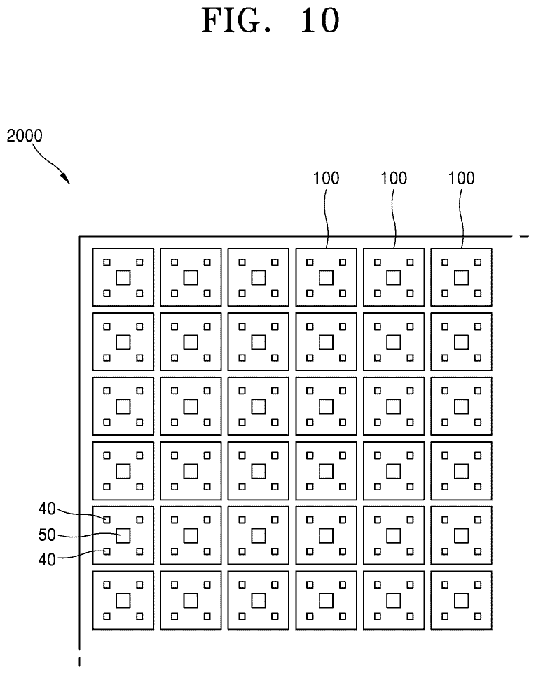

FIG. 10 is a plan view illustrating a display device 2000 according to some embodiments of the present disclosure.

As illustrated in FIG. 10, the display device 2000 according to some embodiments of the present disclosure may include a plurality of wide-area light-emitting driving packages 100 to 400, each forming pixels and arranged in an M-row and N-column configuration to constitute an overall display screen.

Accordingly, the display device 2000 according to the present disclosure can provide excellent visibility due to its wide viewing angle, and can reduce the number of components and manufacturing processes by eliminating the need for additional driver ICs, thereby lowering the product cost and significantly improving productivity.

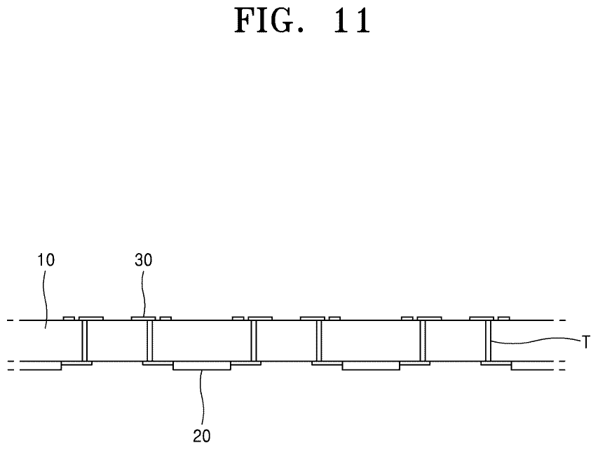

FIGS. 11 to 13 are cross-sectional views sequentially illustrating a manufacturing process of the wide-area light-emitting driving package 100 according to some embodiments of the present disclosure.

As illustrated in FIGS. 11 to 13, the manufacturing process of the wide-area light-emitting driving package 100 according to some embodiments of the present disclosure may be sequentially described as follows.

First, as illustrated in FIG. 11, a substrate 10 is prepared, in which a terminal layer 20 is formed on one surface and a wiring layer 30 electrically connected to the terminal layer 20 through through-electrodes (T) is formed on the opposite surface.

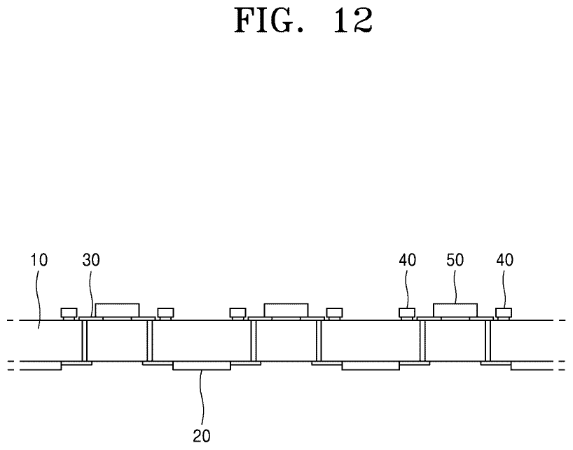

Next, as illustrated in FIG. 12, at least one light-emitting device 40 are mounted on a portion of the wiring layer 30 at a peripheral region of the substrate 10, and a driving element 50 configured to drive the light-emitting devices 40 are mounted on another portion of the wiring layer 30 at a central region of the substrate 10.

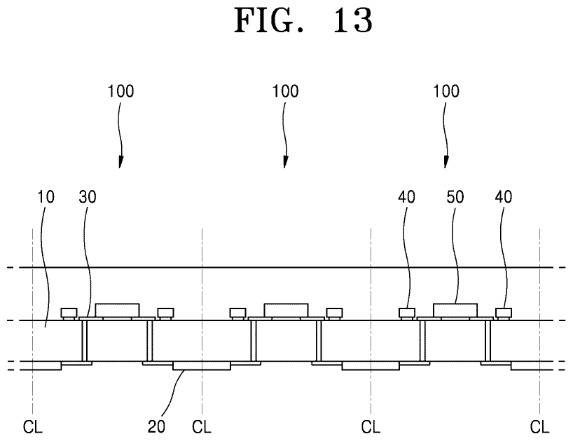

Subsequently, as illustrated in FIG. 13, a protective member 60 covering and protecting the light-emitting devices 40 and the driving element 50 is molded, and the structure is then separated into individual packages by cutting along the cutting lines (CL).

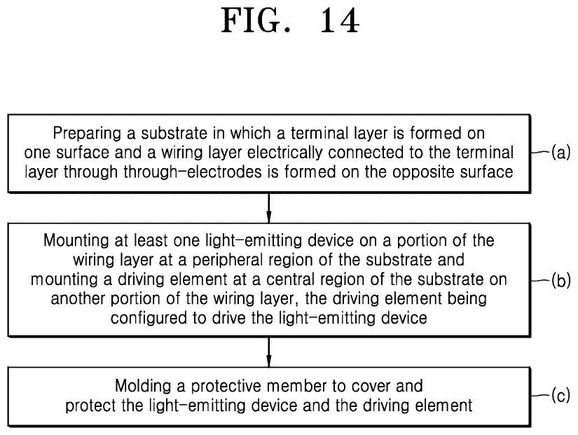

FIG. 14 is a flowchart illustrating a method for manufacturing the wide-area light-emitting driving package according to some embodiments of the present disclosure.

As illustrated in FIGS. 1 to 14, the method for manufacturing a wide-area light-emitting driving package according to some embodiments of the present disclosure may include (a) preparing a substrate 10 in which a terminal layer 20 is formed on one surface and a wiring layer 30 electrically connected to the terminal layer 20 through through-electrodes (T) is formed on the opposite surface, (b) mounting at least one light-emitting device 40 on a portion of the wiring layer 30 at a peripheral region of the substrate 10 and mounting a driving element 50 configured to drive the light-emitting device 40 on another portion of the wiring layer 30 at a central region of the substrate 10, and (c) molding a protective member 60 to cover and protect the light-emitting device 40 and the driving element 50.

Although the present disclosure has been described with reference to the embodiments illustrated in the drawings, these embodiments are merely exemplary. It will be understood by those skilled in the art that various modifications and equivalent other embodiments can be made based on this disclosure. Accordingly, the true technical scope of the present disclosure should be defined by the spirit of the invention described in the appended claims.

What is claimed is:

1. A wide coverage light emitting and driving device package comprising:
a substrate;
a terminal layer formed on one surface of the substrate;
a wiring layer formed on the opposite surface of the substrate and electrically connected to the terminal layer through through-electrodes;
at least one light-emitting device mounted on a portion of the wiring layer and disposed at a peripheral region of the substrate;
a driving element mounted on another portion of the wiring layer, disposed at a central region of the substrate, and configured to drive the light-emitting device; and
a protective member covering and protecting the light-emitting device and the driving element.

2. The wide coverage light emitting and driving device package of claim 1, wherein the light-emitting device includes a plurality of light-emitting devices which are arranged symmetrically around the driving element in diagonal or cross directions to provide wide coverage of the optical path.

3. The wide-area light-emitting driving package of claim 2, wherein the light-emitting devices comprise at least two LEDs arranged respectively in a front-left, front-right, rear-left, and rear-right direction with respect to the driving element, or arranged respectively in a front, rear, left, and right direction with respect to the driving element.

4. The wide-area light-emitting driving package of claim 3, wherein the light-emitting devices includes at least one selected from a red LED, a green LED, a blue LED, a white LED, and combinations thereof.

5. The wide-area light-emitting driving package of claim 1,
wherein the light-emitting device includes a plurality of light-emitting devices, wherein the terminal layer comprises:
at least one pad portion formed at an outer corner region of a bottom surface of the substrate, and
an extension portion extending from the at least one pad portion toward a central region of the bottom surface of the substrate, and wherein the wiring layer comprises
a first wiring portion having one part electrically connected to a pad through-electrode formed in the at least one pad portion and another part connected to the driving element;
a second wiring portion having one part electrically connected to an extension through-electrode formed in the extension portion and another part connected to the driving element; and
a third wiring portion having one part connected to the driving element, another part connected to the light-emitting devices, and another part electrically connected to the pad through-electrode.

6. The wide-area light-emitting driving package according to claim 5, wherein the third wiring portion is formed in a spiral shape that gradually expands outwardly from the driving element, through all the light-emitting devices, to the pad through-electrode in an angular or rounded manner.

7. The wide-area light-emitting driving package of claim 1, wherein
the light-emitting device is a micro-LED or a mini-LED;
the driving element is a driver IC having at least one channel for driving the micro-LED; and
the protective member comprises at least one material selected from silicone, epoxy, phosphor layers, quantum dots, light-transmissive materials, and combinations thereof, molded on the wiring layer.

8. The wide-area light-emitting driving package of claim 7,
wherein the light-emitting device includes a plurality of light-emitting devices,
wherein the protective member comprises at least one selected from a planar molding member having a flat light-emitting surface, a single concentric molding member formed in a circular or polygonal shape with multiple concentric circles centered around a single point, a prism-shaped molding member configured to disperse light by partitioning into regions corresponding to the light-emitting devices, a multiple concentric molding member formed in circular or polygonal shapes with multiple concentric circles centered around respective multiple points corresponding to the light-emitting devices, and combinations thereof.

9. A backlight unit comprising the wide-area light-emitting driving package of claim 1.

10. A display device comprising the wide-area light-emitting driving package of claim 1.
